(19) United States
(12) Patent Application Publication
(10) Pub. No.: US 2006/0011137 A1
(43) Pub. Date: Jan. 19, 2006

(54) Shadow frame with mask panels

(75) Inventor: Ernst Keller, Sunnyvale, CA (US)

Correspondence Address: PATTERSON & SHERIDAN, LLP, 3040 POST OAK BOULEVARD, SUITE 1500, HOUSTON, TX, 77056, US

(73) Assignee: Applied Materials, Inc.

(21) Appl. No.: 11/182,328

(22) Filed: Jul. 14, 2005

Related U.S. Application Data
(60) Provisional application No. 60/588,462, filed on Jul. 16, 2004.

(51) Int. Cl. C23C 16/00

(52) U.S. Cl. 118/720

(57) ABSTRACT

A method and apparatus for masking portions of large area substrates during substrate processing are provided. A shadow frame assembly comprising a shadow frame and one or more mask panels is provided. The shadow frame assembly creates processing apertures that define multiple processing regions on a large area substrate.

### CROSS-REFERENCE TO RELATED APPLICATION

This application claims benefit of U.S. Provisional Application No. 60/588,462, filed Jul. 16, 2004, which is hereby incorporated by reference in its entirety.

### BACKGROUND OF THE INVENTION

1. Field of the Invention

Embodiments of the present invention generally relate to a shadow frame assembly for large area substrates.

2. Description of the Related Art

The ability to process large glass substrates has become important as the demand for large area, flat panel displays such as televisions and computer screens is increasing rapidly. Large area, flat panel displays typically include thin film transistors (TFTs) formed thereon.

The formation of TFTs on large area, flat panel displays or substrates typically includes the deposition of one or more films on the displays by plasma enhanced chemical vapor deposition (PECVD). Depositing uniform thin films across large substrates has proven challenging for several reasons. For example, it is difficult to uniformly heat large area substrates. In addition, plasma conditions often vary across the surface of a large area substrate. Large area substrates are also prone to deformation, such as warping and bowing, as a result of non-uniform heating across the substrate.

Shadow frames have been developed to hold down the edges of large area substrates on a substrate support in a processing chamber during processing to prevent deformation of the substrates. The shadow frames also help prevent unwanted deposition of material on the edges and backside of substrates. However, improved shadow frames are needed, as deposition uniformity is often still an issue even with the use of shadow frames. For example, the shadow frame itself can create non-uniform processing conditions across a substrate by having an uneven substrate contact surface that allows leakage of process gases between the shadow frame and the substrate. Uniformity issues are very critical for large area substrates as a defect in a large area substrate that renders the substrate useless may mean the loss of millions of devices, such as TFTs, with the loss of one substrate.

There also remains a need for a method of dividing large area substrates into multiple components, such as multiple displays. In one aspect, dividing large area substrates can be used to provide multiple displays from one substrate. In another aspect, dividing large area substrates into multiple components may comprise providing multiple screen areas on one large panel.

### SUMMARY OF THE INVENTION

The present invention generally provides a method and apparatus for masking portions of a large area substrate, such as large panels, during substrate processing. In one embodiment, an apparatus for masking portions of a large area substrate during processing includes a shadow frame having one or more mask panels.

In another embodiment, an aluminum shadow frame is provided having one or more mask panels made of ceramic. The mask panels are disposed in a recess formed in the upper surface of the frame to enable contact with a substrate being processed while maintaining a planar upper surface with the frame. In one aspect, the shadow frame assembly creates multiple processing regions on a large substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is an exploded view of an embodiment of a shadow frame assembly of the invention.

FIG. 2A is a cross-sectional view of a region of a shadow frame assembly in which the shadow frame and a mask panel are connected.

FIG. 2B is a cross-sectional view of a region of a shadow frame assembly in which the shadow frame and a mask panel are connected and fastened together.

FIG. 3 is a top plan view of an embodiment of a shadow frame assembly positioned on a substrate support member.

FIG. 4 is a cross-sectional view through lines 4-4 of FIG. 3.

FIG. 4A is an enlarged view of a region of FIG. 4 showing an embodiment of a shadow frame assembly positioned on a substrate support member.

FIG. 5 is an exploded view of another embodiment of a shadow frame assembly of the invention.

FIG. 6 is a schematic cross-sectional view of an exemplary processing chamber having an embodiment of the shadow frame assembly of the invention disposed therein.

FIG. 7 is a sectional view of another embodiment of a fastener securing a mask panel to a shadow frame.

To facilitate understanding, identical reference numerals have been used, wherever possible, to designate identical elements that are common to the figures. It is contemplated that elements of one embodiment may be advantageously utilized in other embodiments without further recitation.

### DETAILED DESCRIPTION

The present invention provides a method and apparatus for masking portions of large area substrates, such as large glass and/or plastic panels, during substrate processing. A shadow frame assembly is provided that includes a shadow frame having one or more mask panels. The shadow frame may be adapted or configured to receive one or multiple mask panels. By masking portions of a large area substrate underlying the shadow frame assembly, multiple isolated processing regions on the substrate can be formed such that material may be selectively deposited on predefined regions (e.g., unmasked areas) of the substrate.

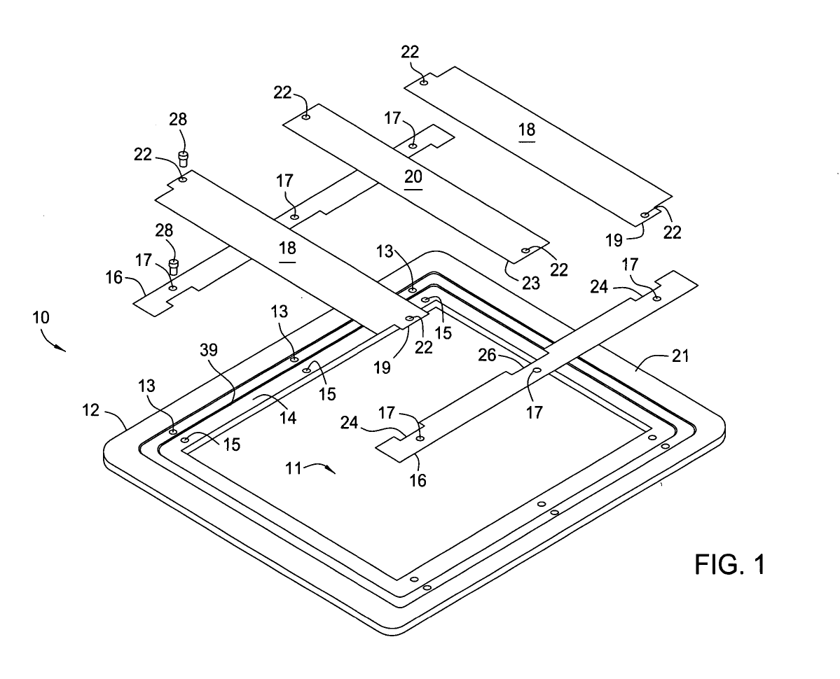

FIG. 1 is an exploded view of one embodiment of a shadow frame assembly 10. The shadow frame assembly 10 comprises a shadow frame 12 and at least one mask panel. In the embodiment depicted in FIG. 1, mask panels 16, 18, and 20 are shown. A substrate is received within the shadow frame 12 and contacted by the mask panels 16, 18, and 20 on a lower surface thereof.

The shadow frame 12 typically has a generally rectangular shape and defines a central aperture 11. Aperture 11 is sized to receive a substrate to be processed therethrough. The shadow frame may have an aperture sized such that the shadow frame can be used with large area substrates, such as substrates having a surface area of at least about 13,000 cm² or at least about 15,000 cm². The shadow frame may have dimensions such that it can be used to process substrates having a surface area of greater than one square meter. The shadow frame 12 may be made of aluminum, ceramic or other suitable material. In one embodiment, the shadow frame 12 is made of aluminum. The shadow frame 12 includes holes 13, 15 in an inner recessed region 14 of the shadow frame 12 circumscribing the central aperture 11. The holes 13, 15 are adapted to receive fasteners 28 that secure the mask panels 16, 18, and 20 to the shadow frame 12.

The inner recessed region 14 of the shadow frame 12 is stepped from the outer region 21 of the shadow frame 12, such that the inner region 14 forms a shelf which accommodates the mask panels 16, 18, and 20 in a substantially co-planar orientation relative to an upper surface of the outer region 21 of the shadow frame. The inner region 14 of the shadow frame may include a stepped surface 39 along an outer edge thereof to support a lateral mask panel and the transverse mask panels along one surface thereof. The stepped surface orients the lateral mask panel at a slight angle in the recess to ensure sealing contact with the substrate once the frame assembly is positioned over the substrate.

The mask panels 16, 18, and 20 may be fabricated from a heat resistant material, such as ceramic or other suitable material, that can withstand chamber processing temperatures, e.g., about 450° C., without substantially bending or warping while having a minimal thickness, such as several hundredths or even several hundred thousandths of an inch. The mask panels may be sized to minimize interference with a gas distribution assembly disposed in the chamber while maintaining the requisite spacing between the glass substrate and the gas distribution assembly. It is contemplated that the panel 20 may be retained by one or more fasteners 28 on a single side so that the panel 20 extends in a cantilevered manner into the interior region 14 defined by the frame 12.

In the embodiment shown in FIG. 1, the shadow frame assembly 10 includes two lateral mask panels 16 that are parallel or approximately parallel to a major axis of the shadow frame 12. The lateral mask panels cover the long edges of a substrate. The lateral mask panels 16 have holes 17 formed therethrough that enable fasteners 28 to be disposed therethrough to fasten the lateral mask panels 16 to the holes 13 formed in the shadow frame 12. The holes 17 may be elongated to allow the fastener 28 to move with holes 13 as the panel expands. The lateral mask panels 16 may have slotted regions 24 that are sized to mate with projecting regions 19 defined at the ends of transverse mask panels 18. The lateral mask panels 16 may have slotted regions 26 that are sized to receive the ends 23 of transverse mask panel 20. In one embodiment, holes 17 may be located adjacent the slotted regions 24 and 26.

In the embodiment depicted in FIG. 1, two terminal transverse mask panels 18 are provided for masking regions of a substrate adjacent the two ends of the lateral mask panels 16 and at least one central transverse mask panel 20 for masking an interior portion of the substrate. The central transverse mask panel 20 masks a region of the substrate disposed between the two terminal transverse mask panels 18. It is contemplated that panels 16, 18, 20 may be arranged to cover other portions of the substrate.

In one embodiment, the transverse mask panels 18, 20 may be substantially parallel to the short axis of the shadow frame 12. In one embodiment, transverse mask panels 18, 20 may be substantially co-planar with and substantially perpendicular to lateral mask panels 16. The transverse mask panels 18, 20 may have holes 22 formed therein. The holes 22 enable fasteners, such as fasteners 28, to be disposed therethrough to fasten the transverse mask panels 18, 20 to the holes 15 formed in the shadow frame 12. The holes 22 may be elongated to accommodate panel expansion. The holes 22 in the terminal transverse mask panels 18 may be located in the projecting regions 19 of the ends of the terminal transverse mask panels 18. The holes 22 in the central transverse mask panel 20 may be located in the ends 23 of transverse mask panel 20.

As shown in FIG. 1, the projecting ends 19 of the terminal transverse mask panels 18 fit into slotted regions 24 of lateral mask panels 16, and the ends 23 of central transverse mask panel 20 fit into the slotted regions 26 of lateral mask panels 16. As the mask panels 16, 18, and 20 are interlocked with each other rather than fastened on top of each other, the total thickness of the mask provided by all of the mask panels is approximately the thickness of one of the mask panels 16, 18, and 20. While fasteners 28 are shown connecting mask panels 16, 18, and 20 to the shadow frame 12, the fasteners may alternatively be used to connect one or more of the mask panels 16, 18, and 20 to each other.

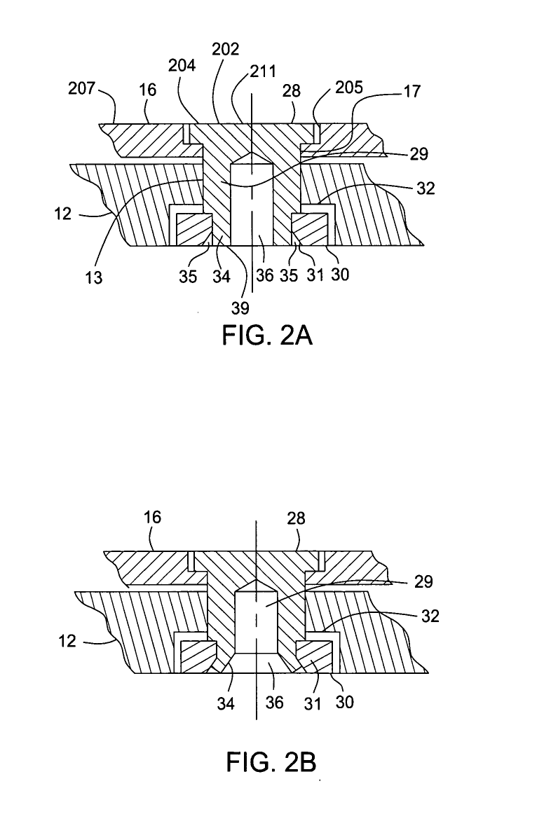

FIG. 2A is a cross-sectional view of a region of the shadow frame assembly 10 in which the shadow frame 12 and a lateral mask panel 16 are connected via fastener 28. In another embodiment, the fastener 28 may be deformable and/or ductile. In one embodiment, the fastener 28 may be fabricated from a metal, such as aluminum. In the embodiment depicted in FIGS. 2A-B, the fastener 28 includes a blind hole 36 formed in a first end 39 of the fastener 28. The first end 39 has a cylinder 34 extending from a main body 29 of the fastener 28. The cylinder 34 has smaller diameter than the diameter of the body 29. A washer 30, such as an aluminum washer, is disposed over the cylinder 34 and abuts the body 29 of the fastener 28. The cylinder 34 and washer 30 are configured to fit at least partially within a recess 32 formed in the underside of the shadow frame 12. The washer 30 has an inner surface 31 that is angled away from the fastener 28 such that there is a space 35 defined between the fastener 28 and the inner surface 31 of the washer 30.

A second end 202 of the fastener 28 includes a head 204 that extends outward from the body 29. The head is configured to prevent the fastener 28 from passing through the hole 17 formed in the lateral mass panel 16. In one embodiment, the head 204 is configured to fit into a recess 205 formed in the upper surface 207 of the lateral mass panel 16, such that the exposed surface 211 of the head 204 is substantially co-planar or recessed below the upper surface 207.

The shadow frame 12 and the lateral mask panel 16 may be fastened together by inserting a tool, e.g., a flaring tool, into the blind hole 36 and the fastener 28, such that the tool flares the first end 39 of the cylinder 34 to abut the inner surface 31 of the washer 30, as shown in FIG. 2B. The flaring tool may be any suitable device for deforming the fastener 28 as depicted in FIG. 2B. When deformed, the fastener 28 is secured to the washer 30, thereby capturing the panel 16 to the shadow frame 12.

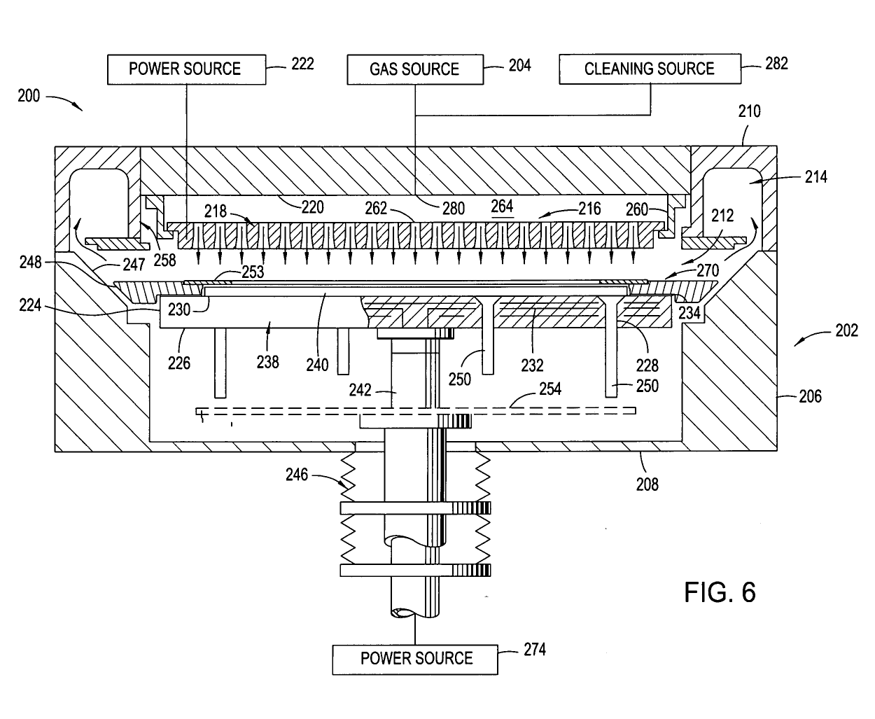

It is contemplated that the washer 30 and fastener 28 may be secured by interference, fit, broaching, staking, braising, welding, riveting, keying or other suitable fastening method. It is also contemplated that the fastener 28 may be a screw, bolt, rivet or other type of fastener suitable for coupling the frame and panels. For example as depicted in FIG. 7, the fastener 28 may include a male threaded member 700 and a female threaded member 702 that engage to secure the panel to the frame. To reduce the height required for the members 700, 702, one or more of the members 700, 702 may include a reduced profile drive 704, such holes for a spanner wrench.

The flaring of the cylinder 34 of the fastener 28 prevents the fastener from being displaced upward past the upper surface of the mask panel 16. Another advantage of working the fastener 28 to secure the washer 30 is that typically the fastener 28 may be shorter than necessary for conventional threaded engagement. A shorter fastener minimizes the amount of separation that the shadow frame assembly provides between the substrate and the gas distribution plate in the chamber during substrate processing. However, alternatively or in combination, the mask panels 16, 18, 20 and the shadow frame 12 may be fastened by alternative methods. It is also contemplated that at least one of the shadow frame 12 or panels 16, 18, 20 may be engaged loosely on the fasteners 28 without fastening.

A further advantage of using the fastener 28 described herein for fastening is that it can allow an appropriate clearance, for example, several thousandths of an inch, between the mask panels and the shadow frame. Such a clearance allows for thermal expansion differences during substrate processing at elevated temperatures between a shadow frame and mask panels made of different materials, such as an aluminum shadow frame and ceramic mask panels.

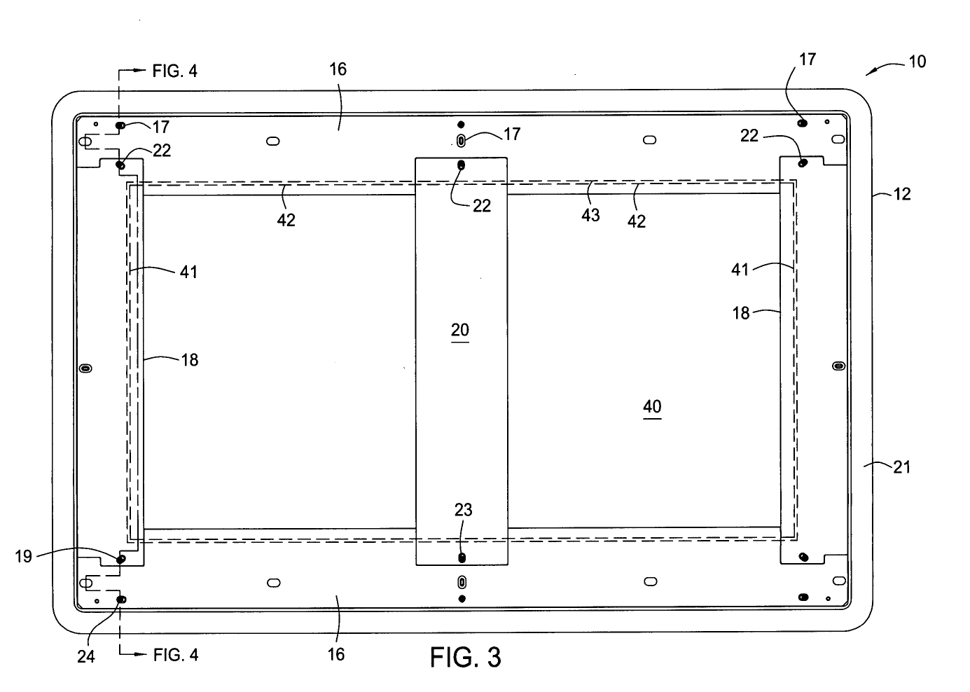

FIG. 3 is a top plan view of the shadow frame assembly 10 of FIG. 1 in an assembled form positioned over a substrate 40 disposed on a substrate support member. The substrate 40 is positioned inward of an edge 43 of the frame 12 defining the inner region 14. Short side edges 41 of the substrate 40 are covered by terminal transverse mask panels 18 and a lateral side edge 42 of the substrate 40 are covered by lateral mask panels 16. As shown in FIG. 3, mask panels 16, 18, 20 are seated in recessed inner region 14 of the mask frame 12. Lateral mask panels 16 and terminal transverse mask panels 18 are seated in an outer portion of the recessed inner region 14, while central mask panel 20 is seated in an inner portion of the recessed inner region 14. In the embodiment shown in FIG. 3, the lateral mask panels 16 do not overlap and are not overlapped by terminal transverse mask panels 18 or central mask panel 20 such that no portion of the lateral mask panels 16 rests on the mask panels 18, 20 or supports a portion of the mask panels 18, 20. The lateral mask panels and the transverse mask panels interlock without overlapping, as slotted regions 24 (FIG. 1) of the lateral mask panels 16 are sized to receive projecting regions 19 of the ends of transverse mask panels 18, and slotted regions 26 of the lateral mask panels 16 are sized to receive the ends 23 (FIG. 1) of transverse mask panel 20.

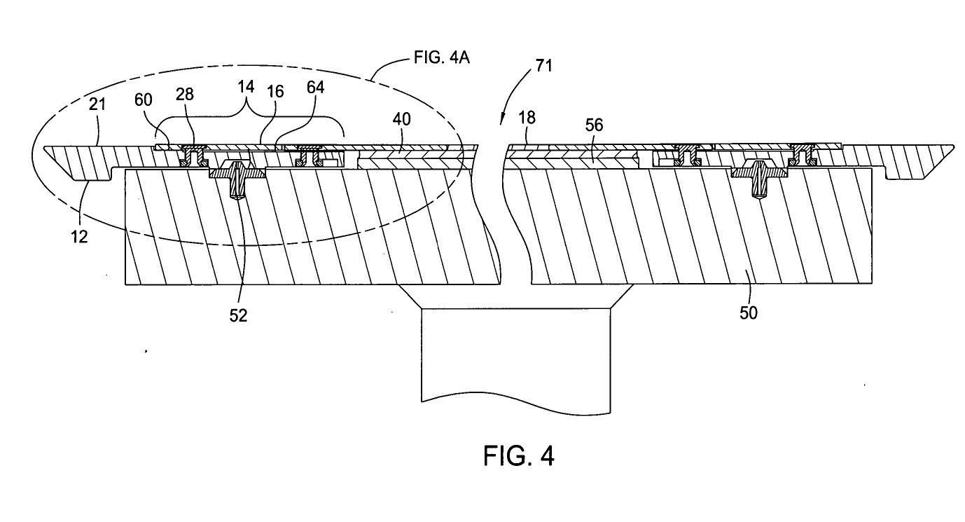

FIG. 4 is a cross-sectional view through lines 44 of FIG. 3. FIG. 4 is shown with break 71 for clarity and to show details of the shadow frame assembly. The shadow frame 12 is supported on substrate support assembly 50. The lateral mask panel 16 and the terminal transverse mask panel 18 are secured to shadow frame 12 by fasteners 28. Substrate 40 is supported by support region 56 of the substrate support assembly 50.

FIG. 4A is an enlarged view of a region of FIG. 4. Lateral mask panel 16 and terminal transverse mask panel 18 are supported in the recessed inner region 14 of the shadow frame. While all of the recessed inner region 14 is lower than the outer region 21 of the shadow frame, the recessed inner region may be angled or stepped such that an outer portion 60 of the recessed inner region 14 is slightly higher, e.g., a few hundredths of an inch, than the inner portion 64 of the recessed inner region 14. It is believed that the higher elevation of the outer portion 60 causes the mask panels 16, 18 to slope inwardly toward the center of the substrate 40 and thus, ensures that the inner edges of the panels 16, 18 contact the substrate 40 to effectively mask the portions of the substrate underlying the panels 16, 18 from deposition.

The panels 516, 518, 520 are secured to the frame 512 by pins 18 as described with reference to the panels 16, 18, 20 and frame 12 above. Referring back to FIG. 1, the shadow frame assembly 10 is assembled by placing fasteners 28 through the holes 17, 22 in the mask panels into the corresponding holes 13, 15 in the shadow frame 12. After all of the fasteners 28 are placed in the holes, the pins are fastened, as described above with respect to FIG. 2B. Mask panels 16, 18, and 20 collectively form a mask defining an outer perimeter having a rectangular shape similar to the shape of the shadow frame 12, wherein the outer perimeter of the mask is smaller than the outer perimeter of the shadow frame 12 and the perimeter of a substrate to be processed so that the edges thereof are masked. The outer perimeter of the mask is formed by lateral mask panels 16 and terminal transverse mask panels 18. The mask is bisected by central transverse mask panel 20 such that the mask defines two apertures between the lateral mask panels 16 and the terminal transverse mask panels 18.

In one embodiment, the outer region 21 of the shadow frame 12 may include a lower surface 402 that extends below and circumscribes a lower surface 400 of the frame 12. A wall 406 extends between the lower surface 402 of the outer region 21 and the lower surface 400 of the inner region of the frame 12. The wall 406 is configured to surround and overlap a wall 408 of the substrate support assembly 50 on which the shadow frame 12 is disposed.

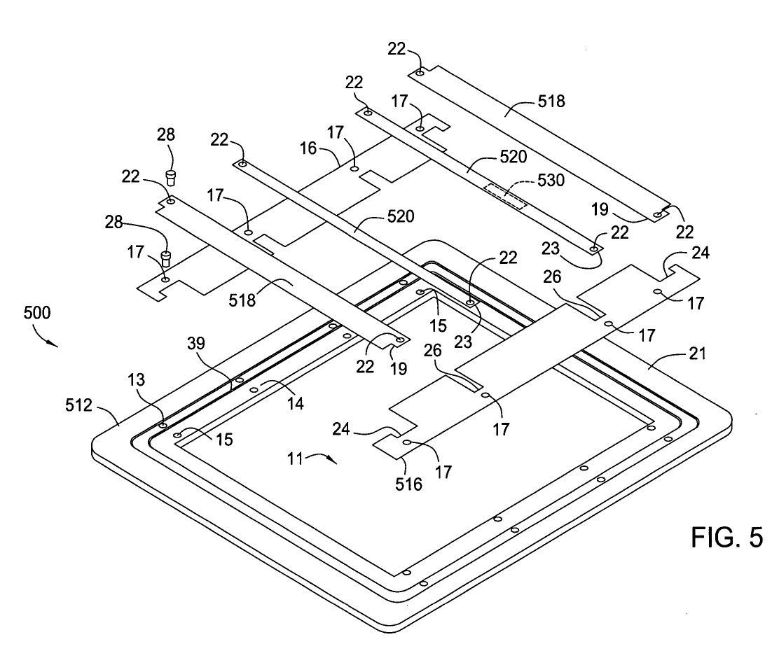

The outer region 21 includes a sloped surface 404 that couples the lower surface 402 of the outer region 21 and an outside edge 410 of the frame 12. The sloped surface 404 facilitates locating and supporting of the shadow frame 12 inside the chamber as shown below in FIG. 6.

The shadow frame assembly 10 of FIG. 1 is configured to form two isolated processing regions on a substrate which define an area for forming a desired display, wherein the perimeter of one of the processing regions is defined by the inner edges of lateral mask panels 16, one edge of the central transverse mask panel 20 and the inner edge of one of the terminal transverse mask panels 18. The perimeter of the other processing region is defined by the inner edges of lateral mask panels 16, the opposing edge of the central transverse mask panel 20 and the inner edge of the other terminal transverse mask panel 18.

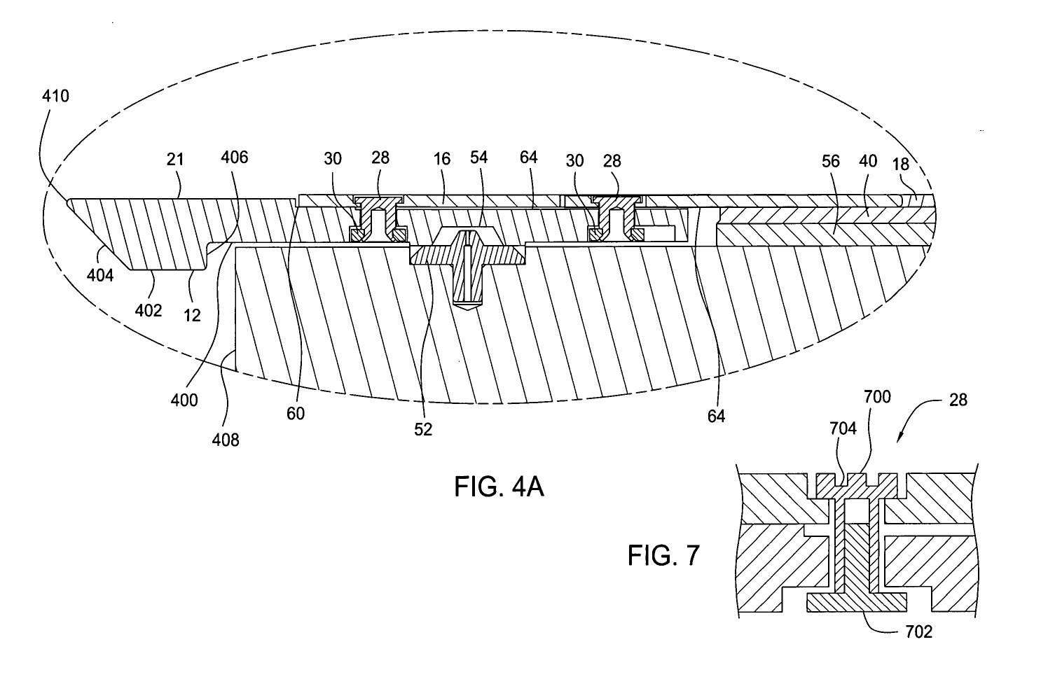

FIG. 5 is an exploded view of another embodiment of a shadow frame assembly 500. Reference numerals from FIG. 1 are used to show identical parts in FIG. 5. While shadow frame assembly 10 in FIG. 1 comprises two terminal transverse mask panels 18 and one central transverse mask panel 20, the shadow frame assembly 500 in FIG. 5 includes a frame 512, two terminal transverse mask panels 518 and two central transverse mask panels 520. Each lateral mask panel 516 of shadow frame assembly 500 includes two slotted regions 26 that are sized to receive the ends 23 of central transverse mask panels 520.

The shadow frame assembly 500 of FIG. 5 is configured to form three isolated processing regions on a substrate. The perimeter of a first isolated processing region is defined by the inner edges of lateral mask panels 516, one edge of one of the central transverse mask panels 520 and the inner edge of one of the terminal transverse mask panels 518. The perimeter of a second isolated processing region is defined by the inner edges of lateral mask panels 516 and the two central transverse mask panels 520. The perimeter of a third isolated processing region is defined by the inner edges of lateral mask panels 516, one edge of the other central transverse mask panel 520 and the inner edge of the other terminal transverse mask panel 518.

As can be seen in FIGS. 1 and 5, the mask panels 516, 58, and 520 can have varying widths. The mask panels 518, 520 may have substantially the same widths, similar to those shown in FIG. 1, or the terminal transverse mask panels 518 and the central transverse mask panels 520 may have different widths, as shown in FIG. 5. The widths of the mask panels 516, 518, and 520 can be chosen to provide processing regions of a desired area on a substrate.

While embodiments of shadow frame assemblies having two lateral mask panels, two terminal transverse mask panels, and one or two central transverse mask panels are shown and described herein, it is contemplated that shadow frame assemblies may include other numbers of mask panels, i.e., two or more lateral mask panels and one or more central transverse mask panels. For example, four processing regions may be provided on a substrate by using a shadow frame assembly comprising three lateral mask panels, one central transverse mask panel, and two terminal transverse mask panels. The panels may be arranged to mask areas of the substrate that are not polygonal in form. One or more of the masks may include an aperture 530 as shown in phantom in FIG. 5. The aperture 530 permits deposit on the substrate to occur through the aperture.

In another embodiment, multiple processing regions may be provided on a substrate by using a shadow frame assembly comprising a one-piece mask rather than a mask comprised of multiple mask panels. For example, a one-piece mask having the shape of the mask formed by mask panels 16, 18, and 20 in FIGS. 1 or 5 may be used. The one-piece mask may be formed as one piece or formed from multiple pieces fused together. The one-piece mask may be made of ceramic.

An example of a substrate processing chamber including a shadow frame assembly as described herein will be described with respect to FIG. 6. FIG. 6 is a schematic cross-sectional view of one embodiment of a plasma enhanced chemical vapor deposition chamber 200, available from AKT, a division of Applied Materials, Inc. of Santa Clara, Calif. The chamber 200 generally includes a processing chamber body 202 coupled to a gas source 204. The processing chamber body 202 has walls 206 and a bottom 208 that partially define a process volume 212. The process volume 212 is typically accessed through a port (not shown) in the walls 206 that facilitate movement of a substrate 240 into and out of the processing chamber body 202. The walls 206 and bottom 208 are typically fabricated from a unitary block of aluminum or other material compatible with processing. The walls 206 support a lid assembly 210 that contains a pumping plenum 214 that couples the process volume 212 to an exhaust port (that includes various pumping components, not shown).

A temperature controlled substrate support assembly 238 is centrally disposed within the processing chamber body 202. The support assembly 238 supports a substrate 240 during processing. In one embodiment, the substrate support assembly 238 comprises an aluminum body 224 that encapsulates at least one embedded heater 232. The heater 232, such as a resistive element, disposed in the support assembly 238, is coupled to a power source 274 and controllably heats the support assembly 238 and the glass substrate 240 positioned thereon to a predetermined temperature. Typically, in a CVD process, the heater 232 maintains the substrate 240 at a uniform temperature between about 150 to at least about 460 degrees Celsius, depending on the deposition processing parameters for the material being deposited.

Generally, the support assembly 238 has a lower side 226 and an upper side 234. The upper side 234 supports the substrate 240. The lower side 226 has a stem 242 coupled thereto. The stem 242 couples the support assembly 238 to a lift system (not shown) that moves the support assembly 238 between an elevated processing position (as shown) and a lowered position that facilitates substrate transfer to and from the processing chamber 202. The stem 242 additionally provides a conduit for electrical and thermocouple leads between the support assembly 238 and other components of the system 200.

A bellows 246 is coupled between support assembly 238 (or the stem 242) and the bottom 208 of the processing chamber 202. The bellows 246 provides a vacuum seal between the chamber volume 212 and the atmosphere outside the processing chamber 202 while facilitating vertical movement of the support assembly 238.

The support assembly 238 generally is grounded such that RF power supplied by a power source 222 to a gas distribution plate assembly 218 positioned between the lid assembly 210 and substrate support assembly 238 (or other electrode positioned within or near the lid assembly of the chamber) may excite gases present in the process volume 212 between the support assembly 238 and the distribution plate assembly 218. The RF power from the power source 222 is generally selected commensurate with the size of the substrate to drive the chemical vapor deposition process.

The support assembly 238 has a plurality of holes 228 disposed therethrough that accept a plurality of lift pins 250. The lift pins 250 are typically comprised of ceramic or anodized aluminum. The lift pins 250 may be actuated relative to the support assembly 238 by an optional lift plate 254 to project from the support surface 230, thereby placing the substrate in a spaced-apart relation to the support assembly 238.

The support assembly 238 additionally supports a shadow frame assembly 270. The shadow frame assembly 270 includes a shadow frame 248 and mask panels, including mask panels 253. The shadow frame assembly 270 covers one or more portions of the substrate 240 during processing so that only predefined regions of the substrate are exposed for receiving deposition materials thereon. The shadow frame assembly 270 may be configured as described above. When the substrate 240 is on the support assembly 238 in a lowered, non-processing position, the shadow frame assembly 270 is supported by the chamber body 202. When the glass substrate 240 is raised into the processing position, the shadow frame assembly 270 is lifted from the chamber body such that the shadow frame assembly is supported by the support assembly 238 and covers portions of the substrate 240.

The lid assembly 210 provides an upper boundary to the process volume 212. The lid assembly 210 typically can be removed or opened to service the processing chamber 202. In one embodiment, the lid assembly 210 is fabricated from aluminum (Al). The lid assembly 210 includes a pumping plenum 214 formed therein coupled to an external pumping system (not shown). The pumping plenum 214 is utilized to channel gases and processing by-products uniformly from the process volume 212 and out of the processing chamber 202.

The lid assembly 210 typically includes an entry port 280 through which process gases provided by the gas source 204 are introduced into the processing chamber 202. The entry port 280 is also coupled to a cleaning source 282. The cleaning source 282 typically provides a cleaning agent, such as disassociated fluorine, that is introduced into the processing chamber 202 to remove deposition by-products and films from processing chamber hardware, including the gas distribution plate assembly 218.

The gas distribution plate assembly 218 is coupled to an interior side 220 of the lid assembly 210. The gas distribution plate assembly 218 is typically configured to substantially follow the profile of the glass substrate 240, for example, rectangular for large area flat panel substrates. The gas distribution plate assembly 218 includes a perforated area 216 through which process and other gases supplied from the gas source 204 are delivered to the process volume 212. The perforated area 216 of the gas distribution plate assembly 218 is configured to provide uniform distribution of gases passing through the gas distribution plate assembly 218 into the processing chamber 202.

The gas distribution plate assembly 218 typically includes a diffuser plate 258 suspended from a hanger plate 260. The diffuser plate 258 and hanger plate 260 may alternatively comprise a single unitary member. A plurality of gas passages 262 are formed through the diffuser plate 258 to allow a predetermined distribution of gas passing through the gas distribution plate assembly 218 and into the process volume 212. The hanger plate 260 maintains the diffuser plate 258 and the interior surface 220 of the lid assembly 210 in a spaced-apart relation, thus defining a plenum 264 therebetween. The plenum 264 allows gases flowing through the lid assembly 210 to uniformly distribute across the width of the diffuser plate 258 so that gas is provided uniformly above the center perforated area 216 and flows with a uniform distribution through the gas passages 262.

It is contemplated that the shadow frame assemblies described herein may be used in other plasma enhanced chemical vapor deposition chambers or in other substrate processing chambers including other chambers for processing large glass panel substrates.

A brief description of the engagement of a shadow frame assembly with a substrate in a processing chamber is provided herein. A shadow frame assembly is lifted from its support (as described with respect to FIG. 6) by the substrate support assembly. Contact pins 52 (FIG. 4A) of a substrate support assembly are received by a recess 54 (FIG. 4A) in shadow frame 12 to ensure alignment of the shadow frame with the substrate support and hence a substrate supported thereon. The substrate has a smaller perimeter than the central aperture 11 of the shadow frame 12. Thus, the substrate is raised through the aperture 11 of the shadow frame 12 and surrounded by the shadow frame 12, as shown in FIG. 3. Mask panels are arranged to cover predefined regions of the substrate to prevent processing, such as deposition of a thin film, on the regions of the substrate disposed underneath the frame assembly.

While the foregoing is directed to embodiments of the present invention, other and further embodiments of the invention may be devised without departing from the basic scope thereof, and the scope thereof is determined by the claims that follow.

What is claimed is:

1. A shadow frame assembly, comprising:
a frame having an upper surface and a stepped lower surface, the frame defining a central aperture; and
at least a first mask panel supported by the frame and covering at least a portion of the aperture.

2. The shadow frame assembly of claim 1, wherein the first mask panel separates two open regions of the aperture.

3. The shadow frame assembly of claim 1, wherein the first mask panel is disposed between two of a plurality of mask panels extending inward from the frame into the aperture.

4. The shadow frame assembly of claim 1 further comprising:
a second mask panel supported by the frame and covering at least a portion of the aperture, wherein the first and second mask panels segment the aperture into at least three open regions.

5. The shadow frame assembly of claim 1, wherein the first mask panel is ceramic and the frame is aluminum.

6. The shadow frame assembly of claim 2, wherein the open regions are polygonal in shape.

7. The shadow frame assembly of claim 1, wherein the frame further comprises:
a recessed region formed in the frame and circumscribing the aperture, the first mask coupled to the recess region.

8. The shadow frame assembly of claim 1 further comprising:
a fastener coupling the frame to the first mask.

9. The shadow frame assembly of claim 8 further comprising:
a washer disposed on the fastener and capturing the frame and first mask between a head of the fastener and the washer, wherein the fastener is secured to the washer by at least one of staking, flaring, peening or interference fit.

10. A shadow frame assembly, comprising:
a frame having a recessed inner region formed on an upper surface and disposed about a central aperture;
one or more lateral mask panels attached to the recessed inner region of the frame; and
one or more transverse mask panels attached to the recessed inner region of the frame, the lateral and transverse mask panels extending past the frame to at least partially cover the central aperture.

11. The shadow frame assembly of claim 10, wherein the one or more of the lateral mask panels are sloped downwardly into the aperture relative to the upper surface of the frame.

12. The shadow frame assembly of claim 10, wherein the recessed inner region comprises a stepped surface along an outer portion thereof, wherein the one or more lateral mask panels are supported on the stepped surface.

13. The shadow frame assembly of claim 10, wherein the one or more of the transverse mask panels is fabricated from a ceramic material.

14. The shadow frame assembly of claim 13, wherein the frame is fabricated from aluminum.

15. The shadow frame assembly of claim 10, wherein the one or more of the lateral mask panels are attached to the frame by a deformable fastener.

16. A shadow frame assembly, comprising:
a frame; and
one or more ceramic mask panels attached to the aluminum frame covering a portion of an aperture formed in the frame.

17. The shadow frame assembly of claim 16, wherein the ceramic mask panels define isolated openings in an aperture formed by the frame.

18. The shadow frame assembly of claim 16, wherein the one or more ceramic mask panels are fastened to the frame in a manner that allows relative movement therebetween.

19. The shadow frame assembly of claim 16, wherein an upper surface of the one or more ceramic mask panels are substantially co-planar with an upper surface of the frame.

20. The shadow frame assembly of claim 17, wherein the open regions of the aperture defined by the one or more panels are polygonal in form.

21. A shadow frame assembly, comprising:
a frame having an upper surface, a lower surface and an outer edge, the frame defining a central aperture;
an outer region of the frame extending below the lower surface;
a sloped surface extending upwards from the outer region to the outer edge of the frame;
a recessed region formed in the upper surface adjacent to and circumscribing the central aperture; and
at least a first mask panel supported by the frame and covering at least a portion of the aperture.

22. The shadow frame assembly of claim 21, wherein the frame and mask panels are fabricated from the same materials.

23. The shadow frame assembly of claim 21, wherein the frame and mask panels are fabricated from the different materials.

24. The shadow frame assembly of claim 21 further comprising:
a second mask panel having an orientation orthogonal to the first mask panel.

25. The shadow frame assembly of claim 21, wherein the first mask panel separates two regions of the aperture.

26. The shadow frame assembly of claim 21, wherein the first mask panel is fastened to the frame in a manner that allows relative movement therebetween.

27. The shadow frame assembly of claim 26, wherein the first mask panel is fabricated from a ceramic material.
